(19) United States
(12) Patent Application Publication
(10) Pub. No.: US 2016/0197101 A1
(43) Pub. Date: Jul. 7, 2016

(54) GRAPHENE DOPED MATERIAL AND MANUFACTURING METHOD THEREOF, AND PIXEL STRUCTURE

(71) Applicants: BOE Technology Group Co., Ltd., Beijing (CN); Beijing BOE Optoelectronics Technology Co., Ltd., Beijing (CN)

(72) Inventors: Jiuxia Yang, Beijing (CN); Jiantao Liu, Beijing (CN); Feng Bai, Beijing (CN)

(21) Appl. No.: 14/808,028

(22) Filed: Jul. 24, 2015

(30) Foreign Application Priority Data
Jan. 6, 2015 (CN) 201510005751.7

(51) Int. Cl. H01L 27/12; C23C 14/24; C23C 16/26

(52) U.S. Cl. CPC H01L 27/1214; C23C 16/26; C23C 14/243

(57) ABSTRACT

Embodiments of the invention provide a graphene doped material and a manufacturing method thereof, and a pixel structure. The graphene doped material comprises at least one graphene layer and at least one dopant layer. Since a dopant material is bonded with graphene, square resistance of the graphene doped material is reduced.

This application claims priority to Chinese Patent Application No. 201510005751.7 filed on Jan. 6, 2015. The present application claims priority to and the benefit of the above-identified application and is incorporated herein in its entirety.

### TECHNICAL FIELD

Embodiments of the invention relate to a graphene doped material and a manufacturing method thereof, and a pixel structure.

### BACKGROUND

Flexible display has become a trend of development in a field of display, and in particular, a wearable device is booming. In the prior art, a pixel electrode is generally made of a transparent conductive material, for example, indium tin oxide (ITO) or indium zinc oxide (IZO), etc.; however, mechanical strength and flexibility of these metal oxides decide that they cannot be well applied to flexible display products.

Therefore, it is necessary to find electrode materials that can be well applied to the flexible display products.

### SUMMARY OF THE INVENTION

Embodiments of the invention provide a graphene doped material and a manufacturing method thereof, and a pixel structure, and the graphene doped material has low square resistance and can be well applied to a flexible display product.

In one aspect, an embodiment of the invention provides a graphene doped material, comprising at least one graphene layer and at least one dopant layer.

In another aspect, an embodiment of the invention further provides a manufacturing method of the graphene doped material described above, comprising: forming at least one dopant layer by vacuum deposition.

In still another aspect, an embodiment of the invention further provides a pixel structure, comprising a thin film transistor, a pixel electrode and/or a common electrode, wherein the pixel electrode and/or the common electrode are/is made of a graphene doped material, the graphene doped material including at least one graphene layer and at least one dopant layer.

### BRIEF DESCRIPTION OF THE DRAWINGS

In order to clearly illustrate the technical solution of the embodiments of the invention, the drawings of the embodiments will be briefly described in the following; it is obvious that the described drawings are only related to some embodiments of the invention and thus are not limitative of the invention.

FIG. 1 is a structural schematic diagram of a graphene doped material in a sixth embodiment of the invention;

FIG. 2 is a schematic diagram of an ADS pixel structure in a twelfth embodiment; and

FIG. 3 is a sectional patterning process of a graphene doped pixel electrode in the twelfth embodiment of the invention.

### DESCRIPTION OF THE EMBODIMENTS

In order to make objects, technical details and advantages of the embodiments of the invention apparent, the technical solutions of the embodiment will be described in a clearly and fully understandable way in connection with the drawings related to the embodiments of the invention. It is obvious that the described embodiments are just a part but not all of the embodiments of the invention. Based on the described embodiments herein, those skilled in the art can obtain other embodiment(s), without any inventive work, which should be within the scope of the invention.

In order to make those skilled in the art better understand the technical solutions of the embodiments of the invention, the embodiments of the invention are further described in detail in conjunction with the drawings.

Exemplarily, a pixel electrode may be made from monolayer graphene in place of ITO. The monolayer graphene can meet an requirement on flexibility, but its square resistance is relatively large; in general, the square resistance of the monolayer graphene is relatively high, up to 120Ω/□ or above, so it is necessary to reduce its square resistance.

### Comparison Example

The present comparison example provides a graphene conductive layer. The graphene conductive layer is made of monolayer graphene, and a test for square resistance and a test for transmittance are conducted on the graphene conductive layer, with results shown in Table 1.

Wherein, a transmittance is obtained by testing an optical transmittance of the conductive layer by a spectrophotometer in a range of 300-1600 nm;

The test for square resistance is conducted by an RTS-9 type four-probe tester, to test a room-temperature square resistance.

### A First Embodiment

The embodiment provides a graphene doped material, the graphene doped material comprising one graphene layer and one dopant layer.

Exemplary, the dopant layer is a FeCl₃ dopant layer, and the FeCl₃ dopant layer has a thickness of 6 nm.

A manufacturing method of the dopant layer in the above graphene doped material is as follows:

1) Placing a dopant material, for example, FeCl₃, in a crucible of a vapor deposition device;

2) Placing a substrate to be doped in a vapor deposition chamber, heating the crucible by an external heat source to perform vapor-depositing;

3) Controlling a depositing rate by controlling a magnitude of current of the heat source, until the dopant layer of a predetermined thickness is deposited.

Exemplarily, the above substrate to be doped may be a substrate on which a graphene layer is formed or a substrate on which a graphene conductive layer needs to be formed; for example, when the graphene conductive layer is used to form a pixel electrode in a display device, the substrate may be a substrate on which a source electrode, a drain electrode . . . and a passivation layer are formed, which is not limited by the embodiment of the invention.

Exemplarily, for the graphene doped material according to the embodiment of the invention, the graphene layer may be firstly formed, and then the dopant layer is formed thereon; or, the dopant layer may be firstly formed, and then the graphene layer is formed thereon; for example, the graphene layer may be formed by chemical vapor deposition or physical vapor deposition, etc.

The vapor deposition device may separately control a material to be deposited, controls a vapor deposition temperature within 300° C.-400° C. and a vacuum degree greater than or equal to 10⁻⁴ Torr, controls the depositing rate by controlling a magnitude of current, and stops depositing until a predetermined thickness is reached.

A test for square resistance and a test for transmittance are conducted on the graphene doped material, with results shown in Table 1.

### A Second Embodiment

The embodiment provides a graphene doped material, the graphene doped material comprising one graphene layer and one dopant layer.

Exemplary, the dopant layer is an MgF₂ dopant layer, and the MgF₂ dopant layer has a thickness of 8 nm.

A manufacturing method of the dopant layer in the above graphene doped material is similar to the method in the first embodiment, and other corresponding description is similar to the first embodiment, which will not be repeated one by one herein.

A test for square resistance and a test for transmittance are conducted on the graphene doped material, with results shown in Table 1.

### A Third Embodiment

The embodiment provides a graphene doped material, the graphene doped material comprising one graphene layer and one dopant layer.

Exemplary, the dopant layer is a BaF₂ dopant layer, and the BaF₂ dopant layer has a thickness of 10 nm.

A manufacturing method of the dopant layer in the above graphene doped material is similar to the method in the first embodiment, and other corresponding description is similar to the first embodiment, which will not be repeated one by one herein.

A test for square resistance and a test for transmittance are conducted on the graphene doped material, with results shown in Table 1.

### A Fourth Embodiment

The embodiment provides a graphene doped material, the graphene doped material comprising three graphene layers and two dopant layers, wherein the graphene layers and the dopant layers are arranged alternately.

Exemplarily, the dopant layers are an MgF₂ dopant layer and a FeCl₃ dopant layer respectively, wherein the MgF₂ dopant layer has a thickness of 6 nm, and the FeCl₃ dopant layer has a thickness of 6 nm.

It should be noted here that an arrangement order between the MgF₂ dopant layer and the FeCl₃ dopant layer may be changed, which is not limited by the embodiment of the invention.

It can be appreciated that the above respective layers may be arranged in other order, as long as a dopant material can be bonded with the graphene, and a transmission rate of carriers can be increased.

A manufacturing method of the dopant layer in the above graphene doped material is similar to the method in the first embodiment, and other corresponding description is similar to the first embodiment, which will not be repeated one by one herein.

A test for square resistance and a test for transmittance are conducted on the graphene doped material, with results shown in Table 1.

### A Fifth Embodiment

The embodiment provides a graphene doped material, the graphene doped material comprising three graphene layers and two dopant layers, wherein the graphene layers and the dopant layers are arranged alternately.

Exemplarily, the dopant layers are BaF₂ dopant layers, wherein the BaF₂ dopant layer has a thickness of 10 nm.

Layers of the graphene doped material may be arranged in an order of a graphene layer, a BaF₂ dopant layer, a graphene layer, a BaF₂ dopant layer, and a graphene layer.

It can be appreciated that the above layers may be arranged in other order, as long as the dopant material can be bonded with the graphene, and a transmission rate of carriers can be increased.

A manufacturing method of the dopant layer in the above graphene doped material is similar to the method in the first embodiment, and other corresponding description is similar to the first embodiment, which will not be repeated one by one herein.

A test for square resistance and a test for transmittance are conducted on the graphene doped material, with results shown in Table 1.

### A Sixth Embodiment

The embodiment provides a graphene doped material, the graphene doped material comprising four graphene layers and two dopant layers.

Exemplarily, the dopant layers are an MgF₂ dopant layer and a FeCl₃ dopant layer respectively, wherein the MgF₂ dopant layer has a thickness of 6 nm, and the FeCl₃ dopant layer has a thickness of 6 nm.

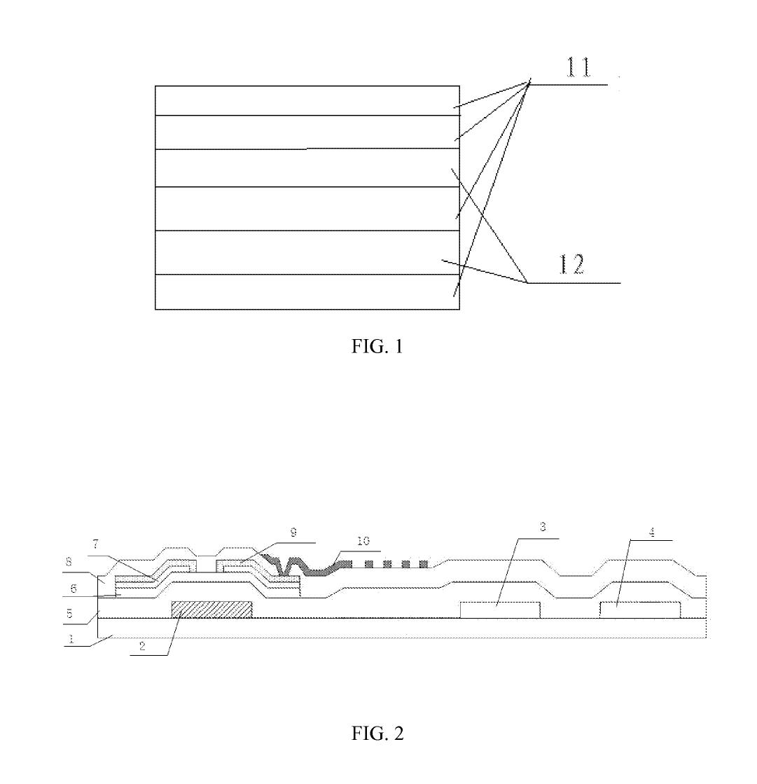

As shown in FIG. 1, 11 denotes the graphene layer, and 12 denotes the dopant layer; and layers of the graphene doped material may be arranged in an order of the graphene layer, the MgF₂ dopant layer, the graphene layer, the FeCl₃ dopant layer, the graphene layer and the graphene layer.

It can be appreciated that the above layers may be arranged in other order, as long as the dopant material can be bonded with the graphene, and a transmission rate of carriers can be increased.

A manufacturing method of the dopant layer in the above graphene doped material is similar to the method in the first embodiment, and other corresponding description is similar to the first embodiment, which will not be repeated one by one herein.

A test for square resistance and a test for transmittance are conducted on the graphene doped material, with results shown in Table 1.

### A Seventh Embodiment

The embodiment provides a graphene doped material, the graphene doped material comprising four graphene layers and three dopant layers.

Exemplarily, the dopant layers are FeCl₃ dopant layers, wherein the FeCl₃ dopant layer has a thickness of 6 nm.

Layers of the graphene doped material may be arranged in an order of the graphene layer, the FeCl₃ dopant layer, the graphene layer, the FeCl₃ dopant layer, the graphene layer, the FeCl₃ dopant layer, and the graphene layer.

It can be appreciated that the above layers may be arranged in other order, as long as the dopant material can be bonded with the graphene, and a transmission rate of carriers can be increased.

A manufacturing method of the dopant layer in the above graphene doped material is similar to the method in the first embodiment, and other corresponding description is similar to the first embodiment, which will not be repeated one by one herein.

A test for square resistance and a test for transmittance are conducted on the graphene doped material, with results shown in Table 1.

### A Eighth Embodiment

The embodiment provides a graphene doped material, the graphene doped material comprising five graphene layers and four dopant layers, wherein the graphene layers and the dopant layers are arranged alternately.

Exemplarily, the dopant layers are an MgF₂ dopant layer, BaF₂ dopant layers, and a FeCl₃ dopant layer respectively, wherein the MgF₂ dopant layer has a thickness of 6 nm, the FeCl₃ dopant layer has a thickness of 6 nm, and the BaF₂ dopant layer has a thickness of 10 nm.

Layers of the graphene doped material may be arranged in an order of the graphene layer, the MgF₂ dopant layer, the graphene layer, the FeCl₃ dopant layer, the graphene layer, the BaF₂ dopant layer, the graphene layer, the BaF₂ dopant layer, and the graphene layer.

It can be appreciated that the above layers may be arranged in other order, as long as the dopant material can be bonded with the graphene, and a transmission rate of carriers can be increased.

A manufacturing method of the dopant layer in the above graphene doped material is similar to the method in the first embodiment, and other corresponding description is similar to the first embodiment, which will not be repeated one by one herein.

A test for square resistance and a test for transmittance are conducted on the graphene doped material, with results shown in Table 1.

### A Ninth Embodiment

The embodiment provides a graphene doped material, the graphene doped material comprising five graphene layers and three dopant layers.

Exemplarily, the dopant layers are BaF₂ dopant layers and a FeCl₃ dopant layer, wherein the FeCl₃ dopant layer has a thickness of 6 nm, and the BaF₂ dopant layer has a thickness of 10 nm.

Layers of the graphene doped material may be arranged in an order of the graphene layer, the FeCl₃ dopant layer, the graphene layer, the BaF₂ dopant layer, the graphene layer, the graphene layer, the BaF₂ dopant layer, and the graphene layer.

It can be appreciated that the above layers may be arranged in other order, as long as the dopant material can be bonded with the graphene, and a transmission rate of carriers can be increased.

A manufacturing method of the dopant layer in the above graphene doped material is similar to the method in the first embodiment, and other corresponding description is similar to the first embodiment, which will not be repeated one by one herein.

A test for square resistance and a test for transmittance are conducted on the graphene doped material, with results shown in Table 1.

### A Tenth Embodiment

The embodiment provides a graphene doped material, the graphene doped material comprising five graphene layers and four dopant layers, wherein the graphene layers and the dopant layers are arranged alternately.

The dopant layers are a BaF₂ dopant layer, an MgF₂ dopant layer and FeCl₃ dopant layers, wherein the FeCl₃ dopant layer has a thickness of 6 nm, the BaF₂ dopant layer has a thickness of 10 nm, and the MgF₂ dopant layer has a thickness of 6 nm.

Layers of the graphene doped material may be arranged in an order of the graphene layer, the FeCl₃ dopant layer, the graphene layer, the FeCl₃ dopant layer, the graphene layer, the MgF₂ dopant layer, the graphene layer, the BaF₂ dopant layer, and the graphene layer.

It can be appreciated that the above respective layers may be arranged in other order, as long as the dopant material can be bonded with the graphene, and a transmission rate of carriers can be increased.

A manufacturing method of the dopant layer in the above graphene doped material is similar to the method in the first embodiment, and other corresponding description is similar to the first embodiment, which will not be repeated one by one herein.

A test for square resistance and a test for transmittance are conducted on the graphene doped material, with results shown in Table 1.

It can be appreciated that the thickness of the above dopant layer may be adjusted according to actual situation, as long as the dopant material can be bonded with the graphene, and the thickness of the dopant layer may be as small as possible.

It can be seen from Table 1 that the transmittances of the graphene doped materials in the first embodiment to the tenth embodiment are maintained at a relatively high level; meanwhile, after the dopant layer and the graphene layer are bonded, the square resistance thereof is reduced greatly compared with that of the monolayer graphene, so the graphene doped materials are more suitable for use as electrode materials for transparent flexible display.

### A Eleventh Embodiment

The embodiment provides an electrode, the electrode comprising the graphene doped material described above.

### A Twelfth Embodiment

The embodiment provides a pixel structure, comprising a thin film transistor, a pixel electrode and/or a common electrode.

It should be appreciated that the pixel structure may adopt a structure such as Twist Nematic (TN) structure, In-Plane Switching (IPS) structure or Advanced Super Dimension Switch (ADS) structure. In the embodiment, it is illustrated by taking the ADS pixel structure as an example, to explain how to make the graphene doped material in the embodiment of the invention into an electrode, example, the pixel electrode and/or the common electrode.

Exemplarily, as shown in FIG. 2, the ADS pixel structure includes: a substrate 1; a gate electrode 2, a common electrode 3 and a gate line 4, disposed on the substrate 1; a gate insulating layer 5, disposed on the gate electrode 2; an active layer 6, disposed on the gate insulating layer 5; an insulating layer 7, disposed on the active layer 6; a source-drain electrode 9, disposed on the insulating layer 7; a passivation layer 8, disposed on the source-drain electrode 9; and a pixel electrode 10, disposed on the passivation layer 8.

A manufacturing method of the ADS pixel structure is described below:

Forming the gate electrode, the common electrode 3, the gate line 4, the gate insulating layer 5, the active layer 6, the insulating layer 7, the source-drain electrode 9, and the passivation layer 8 on a substrate 1 by a patterning process.

A method for forming the above structure can employ a technology known by the inventors, which will not be repeated one by one herein.

Next, forming a graphene doped material on the passivation layer 8.

Exemplarily, a graphene layer 11 may be formed firstly, and the graphene layer 11 may be formed by vapor deposition, which will not be repeated one by one herein.

Forming a dopant layer 12 on the graphene layer by vapor deposition, which may refer to the method in the first embodiment, and shall not be repeated one by one herein.

It can be appreciated that the graphene layers 11 and the dopant layers 12 may be fabricated alternately according to the number of layers and an arrangement order of the graphene layers 11 and the dopant layers 12, to form the graphene doped material of a corresponding structure.

The graphene doped material formed above may be treated by a patterning process:

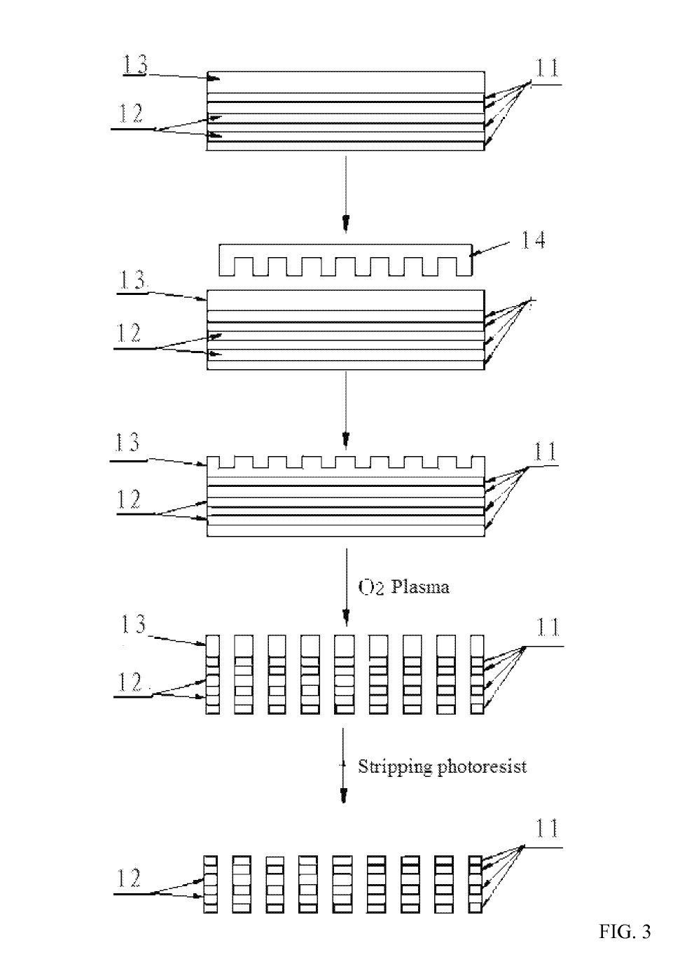

Exemplarily, as shown in FIG. 3, it is treated by steps of:

1) Coating and curing photoresist on the graphene doped material formed above to form a photoresist layer 13 (for example, a PMMA layer);

2) Forming an electrode pattern on the photoresist layer 13 with a mask 14 by a thermal nanoimprint process.

3) Treating the graphene doped material by an etching process, such as, a plasma etching process, to form an electrode.

Exemplarily, process conditions may be as follows: power: 30 W, with a base pressure of 5×10⁻⁸ Torr; working pressure: 30 mTorr; working gas flow: 20 sccm; time: 150 s.

4) Stripping the photoresist layer 13, to form a pixel electrode pattern.

Alternatively, other functional layers may be formed on the pixel electrode, to form the ADS pixel structure.

It can be appreciated that a graphene doped pixel electrode of corresponding pattern may also be fabricated separately, and then the graphene doped pixel electrode is adhered on a corresponding position of the passivation layer 8.

It should be noted that the above process is illustrated by taking the pixel electrode as an example, and is also applicable to other electrodes made of the graphene doped material such as the common electrode, which will not be repeated one by one herein.

For example, the source electrode, the drain electrode or the gate electrode in the thin film transistor may be made of the graphene doped material, and the fabrication method thereof may refer to the above, which will not repeated one by one herein.

### A Thirteenth Embodiment

The present embodiment provides a display device, the display device comprising the above pixel structure.

TABLE 1
Structure and performance testing parameters of graphene doped materials in
comparison example and embodiments

| | | | Comparison | Embodiment | | | | | | | | | |
|---|---|---|---|---|---|---|---|---|---|---|---|---|---|
| Project | | | example | 1 | 2 | 3 | 4 | 5 | 6 | 7 | 8 | 9 | 10 |
| Dopant | BaF₂ | Number of | 0 | | | 1 | | 2 | | | 2 | 2 | 1 |
| material | | layers | | | | | | | | | | | |
| | | Thickness | 0 | | | 10 | | 10 | | | 10 | 10 | 10 |
| | | per layer | | | | | | | | | | | |
| | | (nm) | | | | | | | | | | | |
| | MgF₂ | Number of | 0 | | 1 | | 1 | | 1 | | 1 | | 1 |
| | | layers | | | | | | | | | | | |
| | | Thickness | 0 | | 8 | | 6 | | 6 | | 9 | | 6 |
| | | per | | | | | | | | | | | |
| | | layer | | | | | | | | | | | |
| | | (nm) | | | | | | | | | | | |
| | FeCl₃ | Number of | 0 | 1 | | | 1 | | 1 | 3 | 1 | 1 | 2 |
| | | layers | | | | | | | | | | | |
| | | Thickness | 0 | 6 | | | 6 | | 6 | 6 | 6 | 6 | 6 |
| | | per | | | | | | | | | | | |
| | | layer | | | | | | | | | | | |
| | | (nm) | | | | | | | | | | | |

| Graphene layer (number of | | 1 | 1 | 1 | 1 | 3 | 3 | 4 | 4 | 5 | 5 | 5 |
|---|---|---|---|---|---|---|---|---|---|---|---|---|
| layers) | | | | | | | | | | | | |
| Performance | Transmittance (%) | 98 | 97 | 96.8 | 96.2 | 90.6 | 90.4 | 89.9 | 89.6 | 86.6 | 86.9 | 87.2 |
| | Square resistance | 123 | 76 | 80 | 77.8 | 19 | 18.8 | 16.2 | 14.5 | 7.8 | 9.1 | 8.2 |
| | (Ω/□) | | | | | | | | | | | |

In the graphene doped material and the manufacturing method thereof, and the pixel structure provided by the embodiments of the invention, since the graphene doped material comprises at least one pair of graphene layer and dopant layer in contact with each other, the formed graphene doped material enables a dopant material to be bonded with graphene, increases a transmission rate of carriers, and reduces square resistance of the graphene doped material.

It can be appreciated that the above implementation modes are only exemplary to illustrate principles of the invention, but the invention is not limited thereto. For those of ordinary skill in the art, various changes and modifications can be made without departing from the spirit and essence of the invention, and such changes and modifications are also deemed as the protection scope of the invention.

The application claims priority of Chinese Patent Application No. 201510005751.7 filed on Jan. 6, 2015, the disclosure of which is incorporated herein by reference in its entirety as part of the present application.

What is claimed is:

1. A graphene doped material, comprising at least one graphene layer and at least one dopant layer.

2. The graphene doped material according to claim 1, wherein a number of the dopant layers is two or more.

3. The graphene doped material according to claim 2, wherein any two of the dopant layers are not adjacent.

4. The graphene doped material according to claim 1, wherein the dopant layers comprises any one or several of a BaF₂ layer, a MgF₂ layer and a FeCl₃ layer.

5. The graphene doped material according to claim 1, wherein a total thickness of the dopant layers is 6 nm-35 nm.

6. The graphene doped material according to claim 1, wherein a number of the graphene layers is 1-5.

7. The graphene doped material according to claim 1, wherein the number of the dopant layers is 1-4.

8. The graphene doped material according to claim 2, wherein a number of the graphene layers is two or more.

9. The graphene doped material according to claim 8, wherein the dopant layers and the graphene layers are arranged alternately.

10. The graphene doped material according to claim 1, comprising: at least one pair of the graphene layer and the dopant layer in contact with each other.

11. A manufacturing method of the graphene doped material according to claim 1, comprising: forming at least one dopant layer by vacuum deposition.

12. The manufacturing method of the graphene doped material according to claim 11, wherein the forming at least one dopant layer by vacuum deposition comprises:
placing a dopant material in a vacuum deposition device;
placing a substrate to be doped in a vapor deposition chamber, heating the dopant material and depositing the dopant material on the substrate to be doped.

13. The manufacturing method of the graphene doped material according to claim 12, wherein the vacuum deposition is conducted under a condition of a vacuum degree greater than or equal to 10⁻⁴ Torr at 300° C.-400° C.

14. The manufacturing method of the graphene doped material according to claim 11, further comprising: forming the at least one graphene layer by vapor deposition.

15. The manufacturing method of the graphene doped material according to claim 12, further comprising: forming the at least one graphene layer by vapor deposition, wherein the substrate to be doped is a substrate on which at least one of the graphene layers is formed.

16. A pixel structure, comprising a thin film transistor, a pixel electrode and/or a common electrode, wherein the pixel electrode and/or the common electrode are/is made of a graphene doped material, the graphene doped material comprising at least one graphene layer and at least one dopant layer.

17. The pixel structure according to claim 16, wherein the thin film transistor comprises a gate electrode, a gate insulating layer, an active layer, a source electrode and a drain electrode formed sequentially, wherein at least one of the gate electrode, the source electrode and the drain electrode is made of the graphene doped material.
